(19) United States
(12) Patent Application Publication
(10) Pub. No.: US 2012/0092026 A1
(43) Pub. Date: Apr. 19, 2012

(54) Electrical System, Method, and Apparatus of Fingerprint Sensor Using Acoustic Impediography

(75) Inventors: Christian Liautaud, Boca Raton (HT); Rainer M. Schmitt, Palm Beach Gardens (DE)

(73) Assignee: Sonavation, Inc., Palm Beach Gardens, FL (US)

(21) Appl. No.: 13/277,021

(22) Filed: Oct. 19, 2011

Related U.S. Application Data
(60) Provisional application No. 61/394,569, filed on Oct. 19, 2010.

(51) Int. Cl. G01R 27/28; G01H 5/00

(52) U.S. Cl. 324/649; 73/645

(57) ABSTRACT

Provided is a method of arranging a plurality of sensor elements to form a sensor array. The method includes arranging the plurality of elements to form two or more sub-rows along an axis. Elements in a first of the two or more sub-rows are positioned in a staggered arrangement with the elements in a second of the two or more sub-rows.

### CROSS-REFERENCE TO RELATED APPLICATIONS

This application claims benefit to U.S. Provisional Application No. 61/394,569, filed on Oct. 19, 2010, which is incorporated herein by reference.

### BACKGROUND OF THE INVENTION

1. Field of the Invention

The present invention relates to biometric sensing. More particularly, the present invention relates to capturing a biometric imprint using one or more sensor arrays.

2. Background Art

There are several different types of Fingerprint sensor electrical system on the market: optical, capacitive, RF, thermal, and Infra-red (amongst others). They all offer a unique combination of price, performance, reliability, and form factor. All make compromises in order to excel in select areas. None can claim to be the best in all areas.

This patent describes a new kind of fingerprint sensors based on the principle of Acoustic Impediography. A Fingerprint sensor using Acoustic Impediography is comprised of an Application Specific Integrated Circuit (ASIC or IC) and an array of mechanical oscillators used as sensing elements. It provides better price, performance, reliability, and form factor than the current state of the art fingerprint sensors.

### BRIEF SUMMARY OF THE INVENTION

Consistent with the principles of the present invention, as embodied and broadly described herein, the present invention includes an electrical system and method to capture a fingerprint using the principle of Acoustic Impediography. The system includes an integrated circuit and an array of mechanical oscillators used as sensing elements.

The present invention provides a unique system and method to capture fingerprints. The principle of Acoustic Impediography is used by measuring the amount of electrical current flowing through each mechanical oscillator when excited with an electrical signal at a specific frequency. When the current is measured in each sensing element, an image of the fingerprint (or portions of it) can be built using the system described in this patent.

Further embodiments, features, and advantages of the present invention, as well as the structure and operation of the various embodiments of the present invention are described in detail below with reference to accompanying drawings.

### BRIEF DESCRIPTION OF THE DRAWINGS/FIGURES

The accompanying drawings illustrate the present invention and, together with the description, further serve to explain the principles of the invention and to enable one skilled in the pertinent art to make and use the invention.

FIG. 1 is an illustration of the sensor array made of mechanical oscillators arranged in rows and columns;

FIG. 2 is an illustration of the ASIC transmit and receives lines connected to the sensor array shown in FIG. 1;

FIG. 3 is an illustration of a finger on the sensor array during capture of the fingerprint;

FIG. 4 is an illustration of transmitter section of the ASIC;

FIG. 5 is an illustration of receiver pipeline section of the ASIC,

FIG. 6 is an illustration of the impedance of the mechanical oscillators over frequency,

FIG. 7 is an illustration of the electrical current fingerprint ridge and valleys over time,

FIG. 8 is an illustration of the ASIC receiver pipeline with a multiplexer,

FIG. 9 is an illustration of the ASIC receiver pipeline with a multiplexer placed at the beginning of the pipeline,

FIG. 10 is an illustration of the ASIC receiver pipeline with a multiplexer and one set of sample and holds,

FIG. 11 is an illustration of the ASIC receiver pipeline with a multiplexer and multiple sets of sample and holds,

FIG. 12 is an illustration of the sample time without sample and holds.

FIG. 13 is an illustration the sample time with sample and holds.

The present invention will now be described with reference to the accompanying drawings. In the drawings, like reference numbers generally indicate identical, functionally similar, and/or structurally similar elements. The drawing in which an element first appears is indicated by the leftmost digit(s) in the reference number.

### DETAILED DESCRIPTION OF THE INVENTION

This specification discloses one or more embodiments that incorporate the features of this invention. The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Furthermore, when a particular feature, structure, or characteristic is described in connection with an embodiment, it is submitted that it is within the knowledge of one skilled in the art to affect such feature, structure, or characteristics in connection with other embodiments whether or not explicitly described.

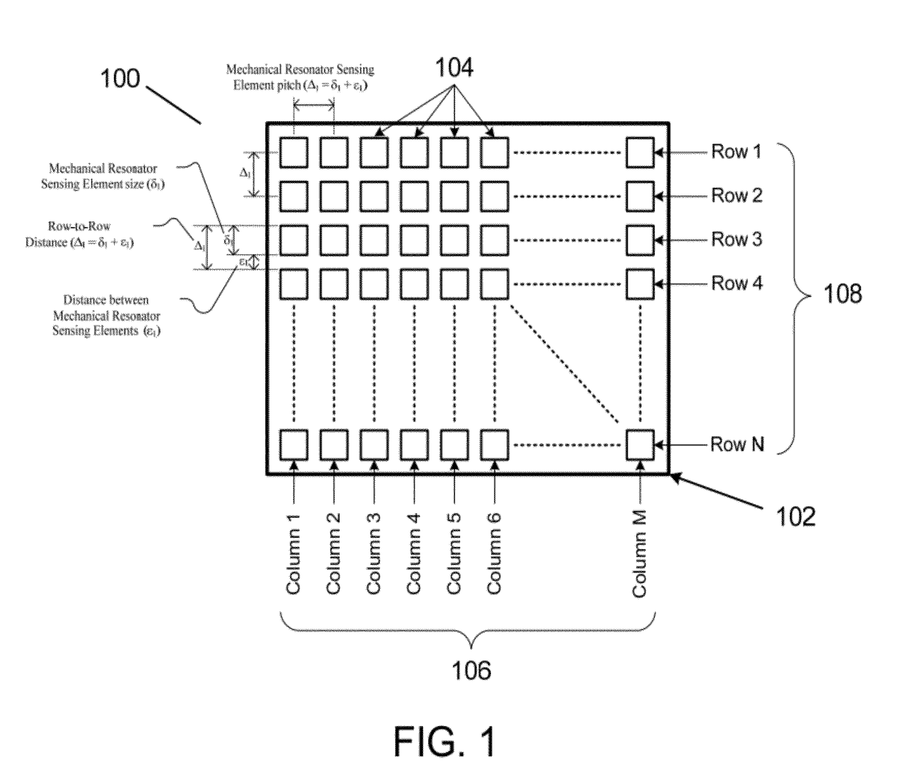

FIG. 1 A Fingerprint sensor using Acoustic Impediography is comprised of an Application Specific Integrated Circuit (ASIC or IC) and an array of mechanical oscillator used as sensing elements. The array of sensing elements contains multiple sensing elements arranged in rows and columns as shown in FIG. 1

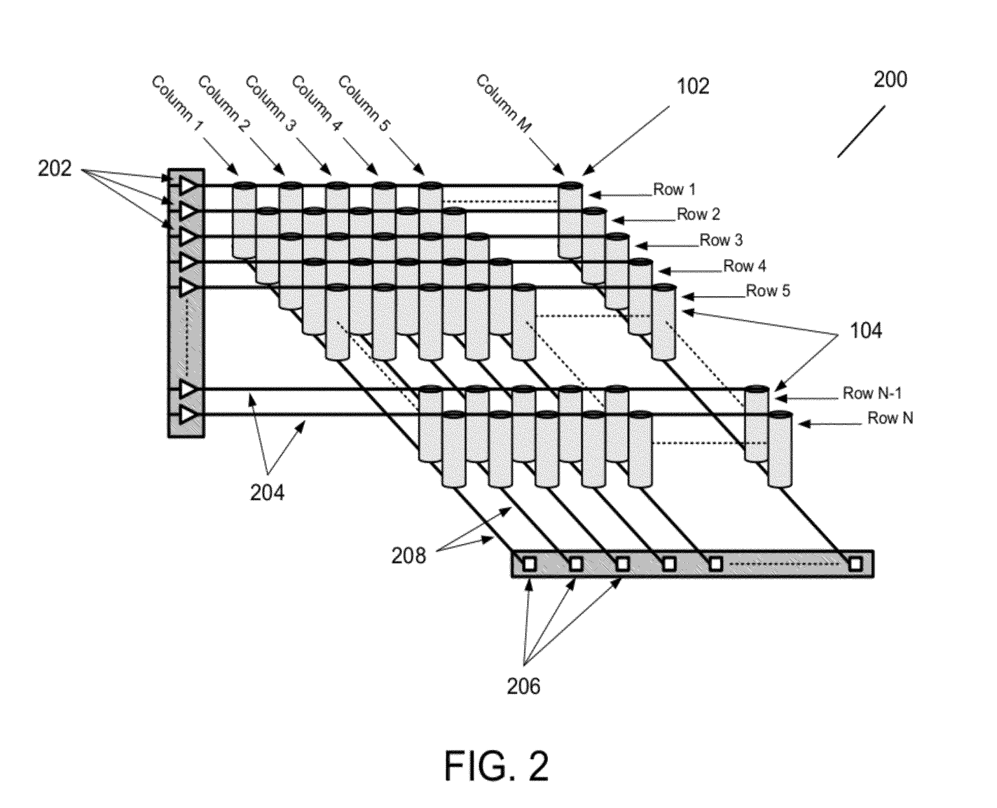

Each sensing element is uniquely addressable by the Integrated Circuit using transmitters and receivers inside the IC. Each row of sensing elements is connected to a single transmitter inside the IC. In addition, each column of sensing elements is connected to a single receiver inside the IC as shown in FIG. 2.

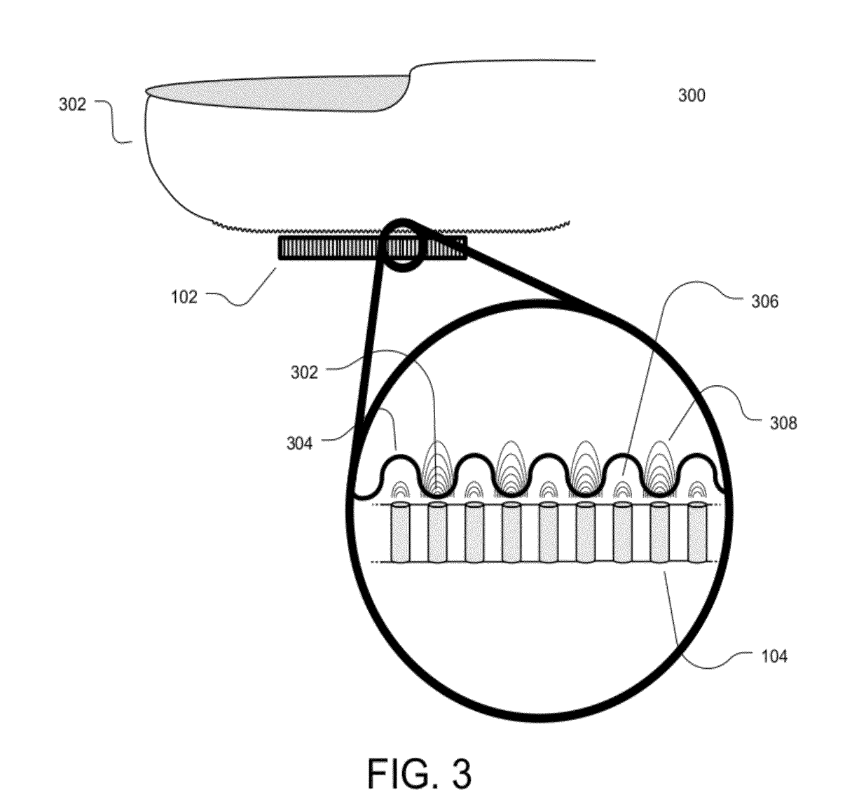

The IC uses its integrated transmitters to generate an electrical signal that creates a mechanical oscillation of the sensing elements. This mechanical oscillation generates an acoustic wave above and below each sensing elements. Finger ridge and valleys will present different acoustic load (or impedance) on the individual sensing elements. Depending on this acoustic impedance of the finger ridge and valleys on the sensor, the acoustic wave generated by the sensing elements will be different as shown in FIG. 3.

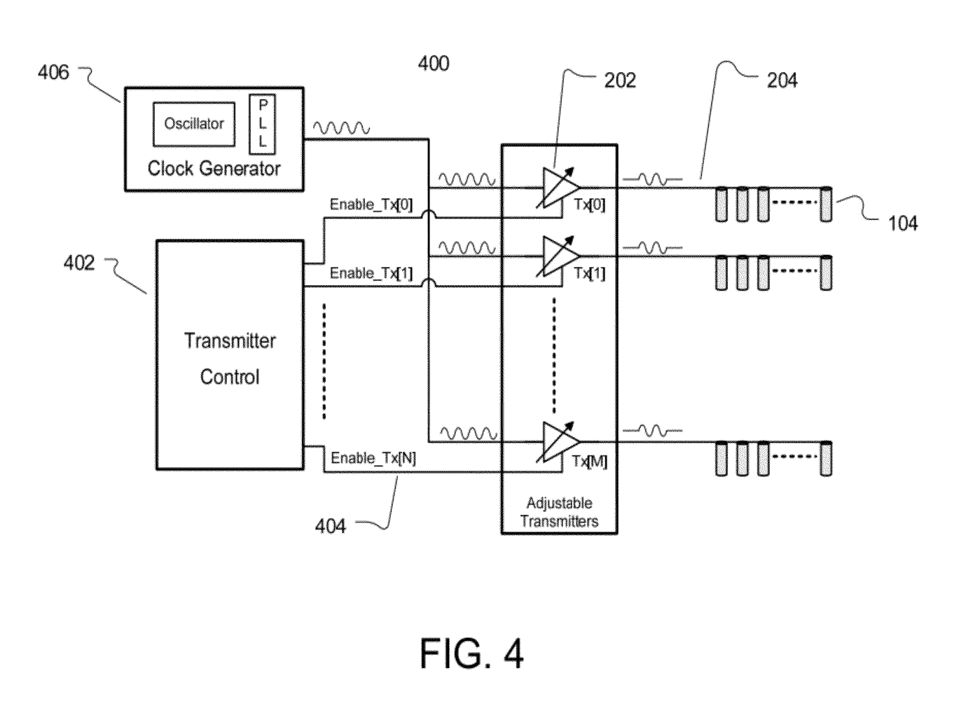

The ASIC has integrated transmitters connected to each row of the sensor array. Each transmitter is individually controlled by a “Transmitter Control” block. This control block determines the timing of each individual transmitter. It also controls the amplitude of the signal generated by each transmitter. It is advantageous for the transmitters to generate a sinusoidal shaped signal with a frequency matching the resonant frequency of the sensing elements. Either the series or the parallel resonance (or both) of the mechanical oscillator sensing elements could be used. A programmable “Phased Lock Loop” (PLL) is used to generate the desired frequency generated the by transmitters as shown in FIG. 4.

The ASIC contains receivers connected to each column of the sensor array. When a single transmitter is enabled, a receiver is used to measure the amount of current flowing through a single sensing elements. Each receiver pipeline is comprised of the following elements: An input pin, A current-to-voltage converter/amplifier, A noise filter, Signal conditioning circuits, Adjustable gain and offset, and an Analog-to-Digital Converter.

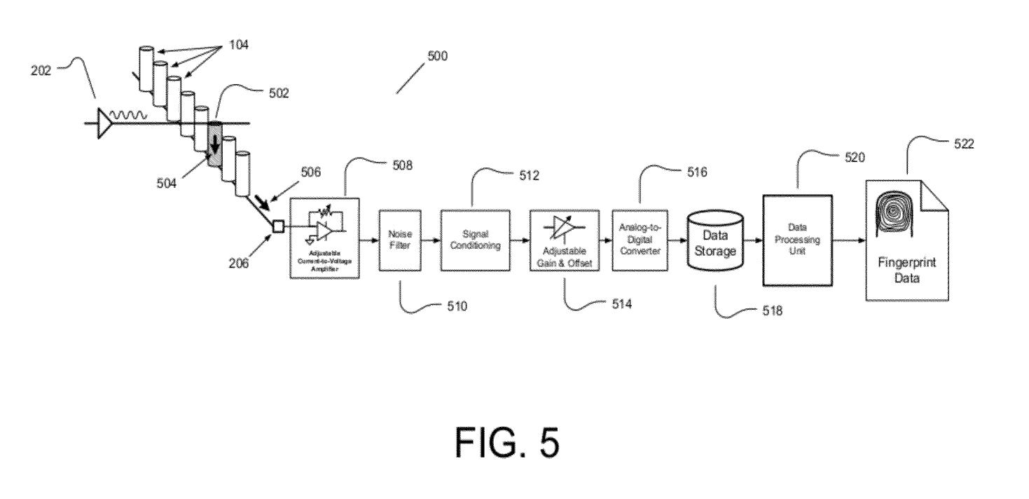

Once the analog signal has been converted to a digital signal by the Analog-to-Digital Converter (ADC), it is stored into a data storage system to be processed and converted into a fingerprint image as shown in FIG. 5.

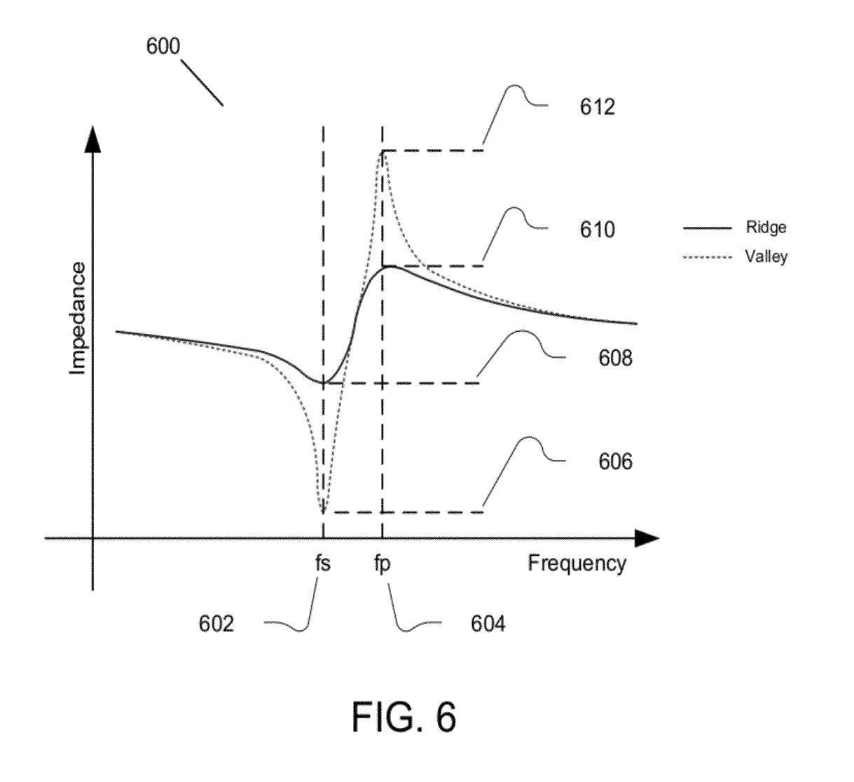

The amount of current measured by the receiver is inversely proportional to the impedance of the individual sensing element. Which itself is proportional to the acoustic impedance of the ridge or valley on this sensing element. At the series resonant frequency the finger valley impedance is lower than the finger ridge impedance. And at the parallel resonant frequency, the finger ridge impedance is lower than the finger valley impedance as shown in FIG. 6.

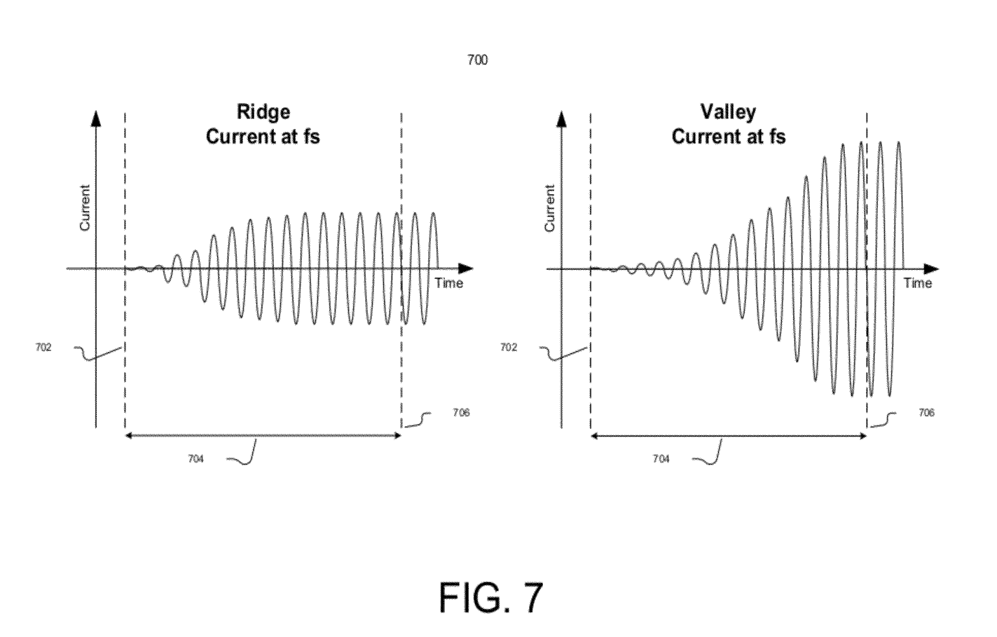

The current flowing through the sensing elements will buildup from the time the transmitter is enabled, until it reaches a steady state. This buildup time is due to the mechanical characteristics of the sensing elements. The impedance difference between ridge and valley will create different current amplitudes in the selected sensing elements as shown in FIG. 7.

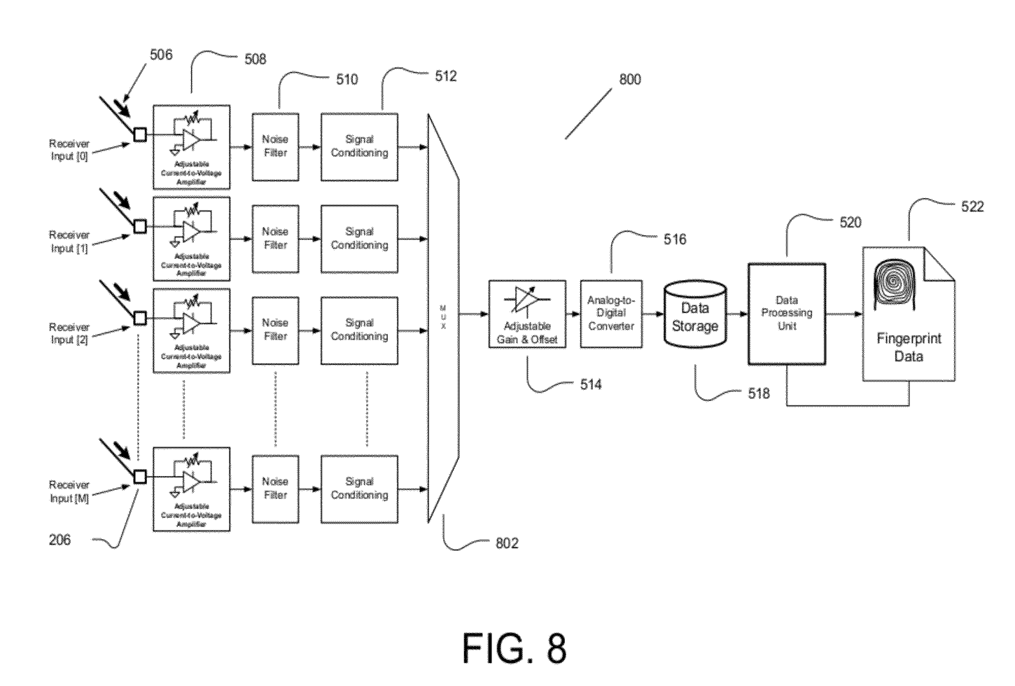

Each component in a receiver pipeline could be shared with other receiver pipelines. The ability to share components reduces the amount of circuitry inside the ASIC. FIG. 8 shows an example where the “Adjustable Gain and Offset”, and the “Analog-to-Digital Converter” are shared with other receivers. A multiplexer is used to switch the signals coming from each receiver feeding the “Adjustable Gain and Offset”, and the “Analog-to-Digital Converter”.

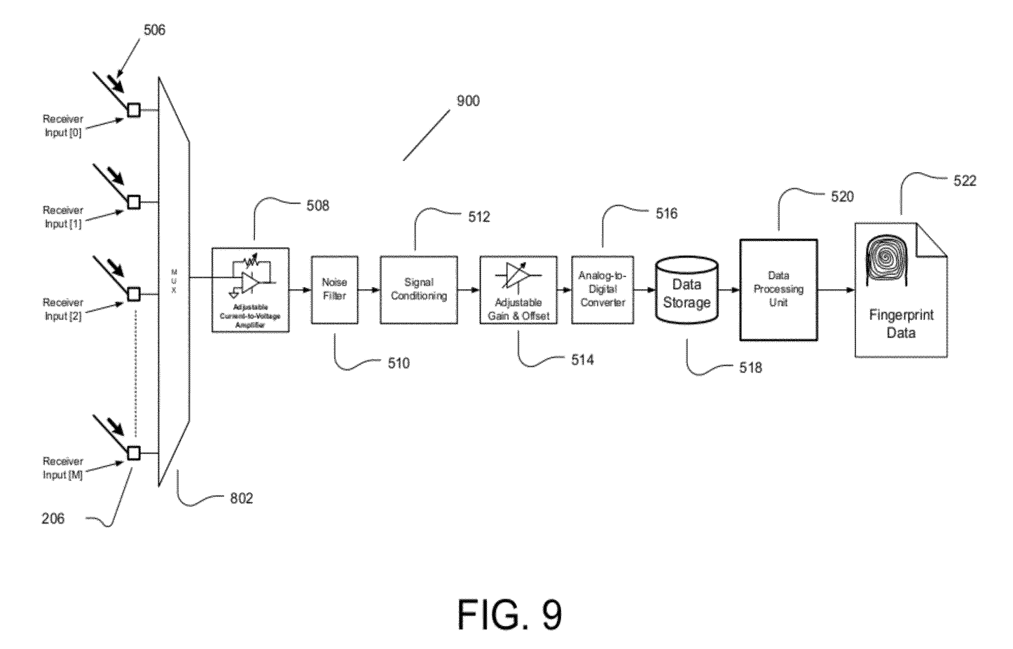

The multiplexer placement in the pipeline can vary depending on the application and performance requirements. FIG. 9 shows an example where every component in the pipeline (except for the input pin) are shared between receivers.

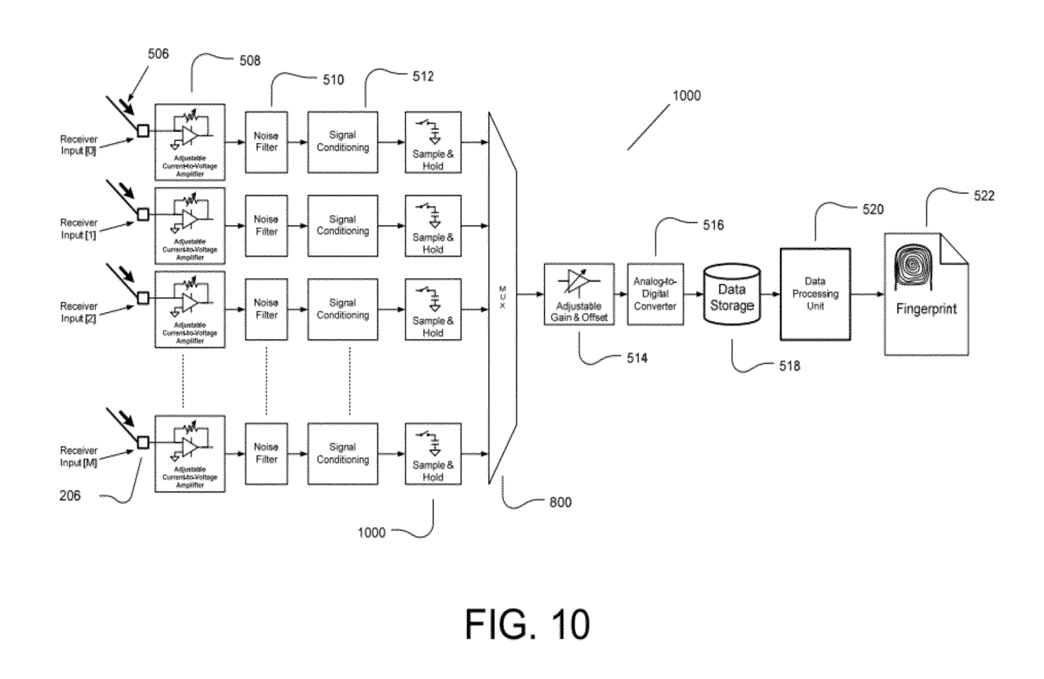

To improve performance sample and hold circuits can be used to break the pipeline into time slices. Different sections of the receiver pipeline can work on different sensing element data at different times. FIG. 10 shows an example where “Sample and Hold” circuits are inserted between the “Signal Conditioning” and “Adjustable Gain and Offset” blocks. Therefore, the section from the receiver input pin to the “Signal Conditioning” block are working on the next sensor element data, while the section from the “Adjustable Gain and Offset” to the “Analog-to-Digital Converter” are working on the current sensor element data.

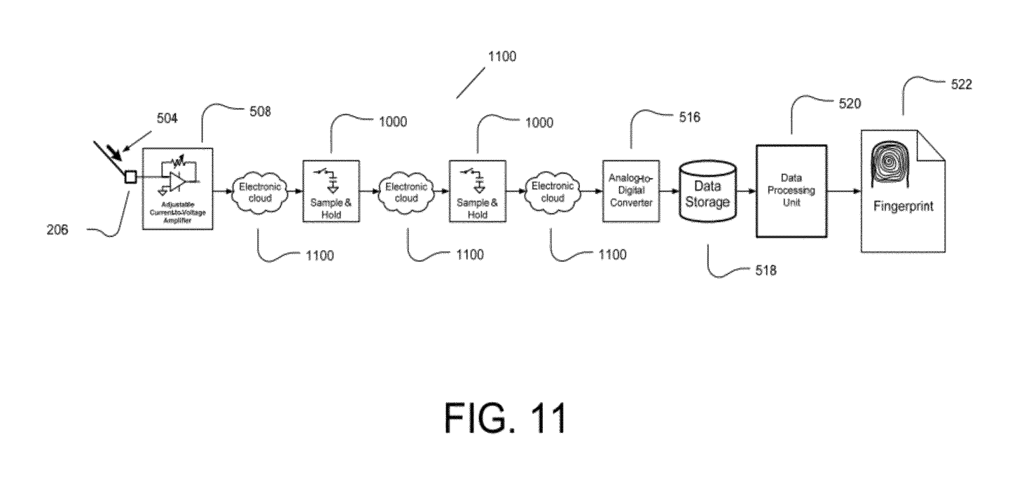

This concept of time slicing the receiver pipeline could be modified and expended as shown in FIG. 11, where multiple “Sample and Holds” are used along the pipeline. The “electronic cloud” represents any electrical component in the receiver pipeline.

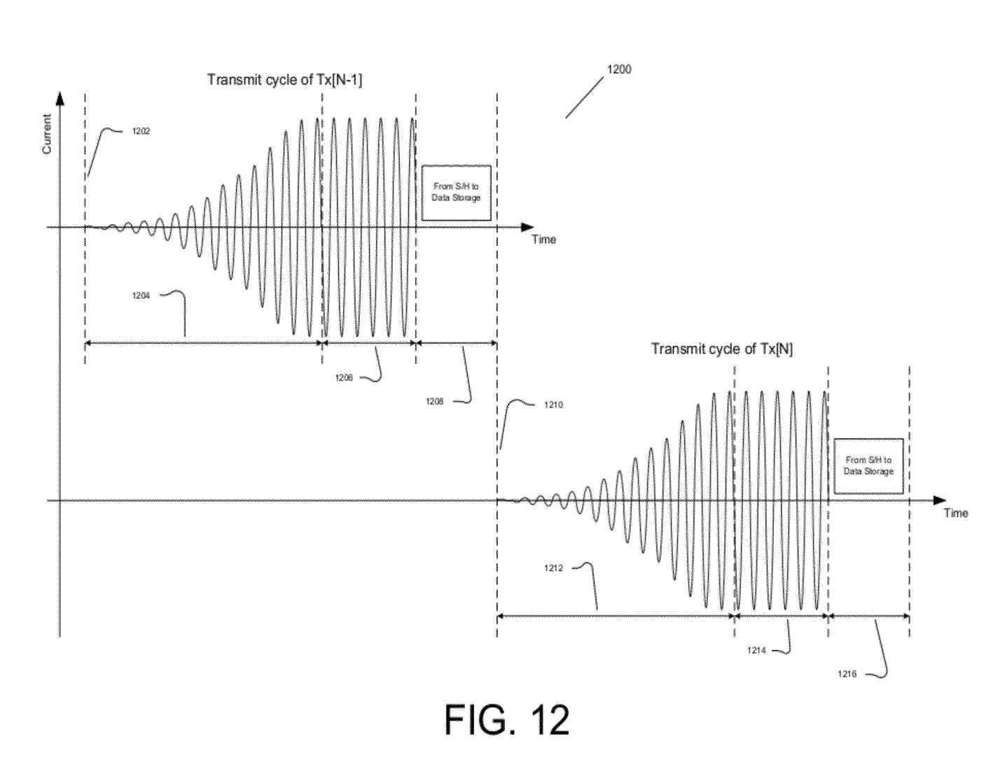

FIG. 12 shows the current from the sensing elements in the receiver pipeline over time without any “Sample and Hold”.

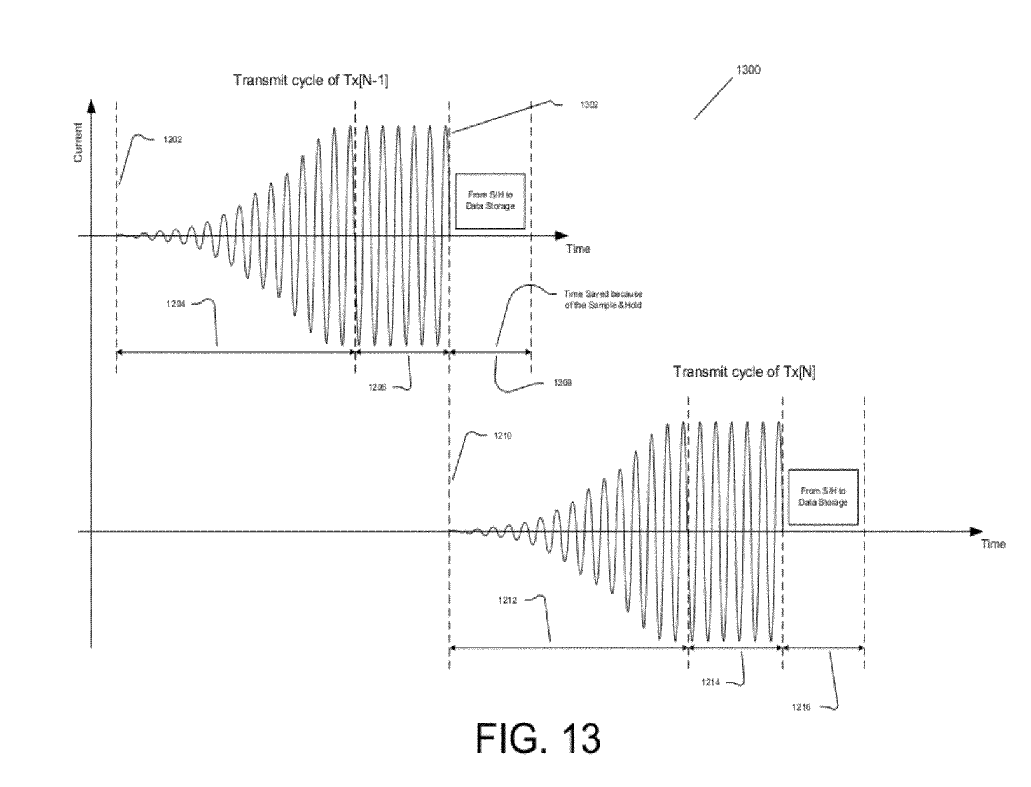

FIG. 13 shows the current from the sensing elements in the receiver pipeline over time with the same set of “Sample and Hold” as shown in FIG. 10. One can see the overlap in time between the two sets of data from two different sensing elements. The amount of overlap is proportional to the amount of time it takes to sample every sensing element in the sensor array. Which itself is proportional to the system performance.

### CONCLUSION

Example embodiments of the methods, systems, and components of the present invention have been described herein. As noted elsewhere, these example embodiments have been described for illustrative purposes only, and are not limiting. Other embodiments are possible and are covered by the invention. Such other embodiments will be apparent to persons skilled in the relevant art(s) based on the teachings contained herein. Thus, the breadth and scope of the present invention should not be limited by any of the above described exemplary embodiments, but should be defined only in accordance with the following claims and their equivalents.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

What is claimed is:

1. A fingerprint sensor, comprising: mechanical oscillators, and an electrical system to measure the impedance and/or the electrical current through each mechanical oscillator.

2. The method of claim 1, wherein groups of mechanical oscillators form an array arranged in rows and columns.

3. The method of claim 1, wherein the mechanical oscillators are used to measure the acoustic impedance of the finger.

4. The method of claim 1, wherein the mechanical oscillators are excited with an electrical signal with a specific oscillation frequency to maximize the received signal quality and reduce signal to noise ratio.

5. The method of claim 1, wherein the electrical signal used to excite the mechanical oscillators is generated with one or multiple adjustable transmitters, where the transmitters have adjustable voltage amplitude and/or frequency controls.

6. The method of claim 1, wherein the fingerprint electrical system is comprised of: current to voltage converters, noise filters, signal conditioning, adjustable gain and offset, analog to digital converters, data storage, and fingerprint data processing unit.

7. The method of claim 6, wherein one or more multiplexers are used to reduce the amount and complexity of the electrical circuit.

8. The method of claim 6, wherein electrical signal sample and hold circuits are used to reduce scan time and increase performance.
